(19) United States
(12) Patent Application Publication
(10) Pub. No.: US 2003/0100133 A1
(43) Pub. Date: May 29, 2003

(54) System-on-chip breakpoint synchronization

(76) Inventors: Michael A. Eidson, Gilbert, AZ (US); Yan Xu, Phoenix, AZ (US)

Correspondence Address: FISH & RICHARDSON, PC, 4350 LA JOLLA VILLAGE DRIVE, SUITE 500, SAN DIEGO, CA, 92122, US

(21) Appl. No.: 09/994,483

(22) Filed: Nov. 26, 2001

(51) Int. Cl. H01L 21/66

(52) U.S. Cl. 438/16

(57) ABSTRACT

Handling breakpoints includes suspending execution of a peripheral and saving the state of the peripheral in response to a first signal indicating the execution of a breakpoint by a processor. Execution of the breakpoint by the processor is continued in response to receiving a second signal indicating that the state of the peripheral has been saved. The saved state of the peripheral is restored, in response to a third signal indicating the completion of the execution of the breakpoint by the processor.

### BACKGROUND

This invention relates to system-on-chip (SOC) breakpoint handling.

A SOC can include a system monolithically fabricated on a single wafer. The SOC may include digital components such as independent processors and peripherals configured to interact with one another. Embedded systems are natural candidates for SOC implementations because their hardware needs including processor, memory, and application-specific circuitry can be met with SOC technology. Integration, though attractive in terms of overall system cost and performance, presents certain problems related to debugging these systems.

Isolating a hardware or software defect within the SOC often requires using a debugging tool to set a breakpoint condition for a processor in the SOC. Once the condition is satisfied, the processor and the peripherals are stopped and the breakpoint handler is executed. After stepping through the breakpoint handler to isolate the problem, the processors and peripherals are restarted. However, the internal architecture of a typical SOC lacks the ability to effectively stop and restart multiple independent processors and peripherals without the experiencing loose of synchronization among the components in the SOC.

### BRIEF DESCRIPTION OF THE DRAWINGS

FIG. 1 is a block diagram of a debugging environment.

FIG. 2 is a block diagram of a SOC.

FIG. 3 is a block diagram of a digital logic circuit for handling breakpoints.

FIG. 4 is a flow chart for handling breakpoints.

### DETAILED DESCRIPTION

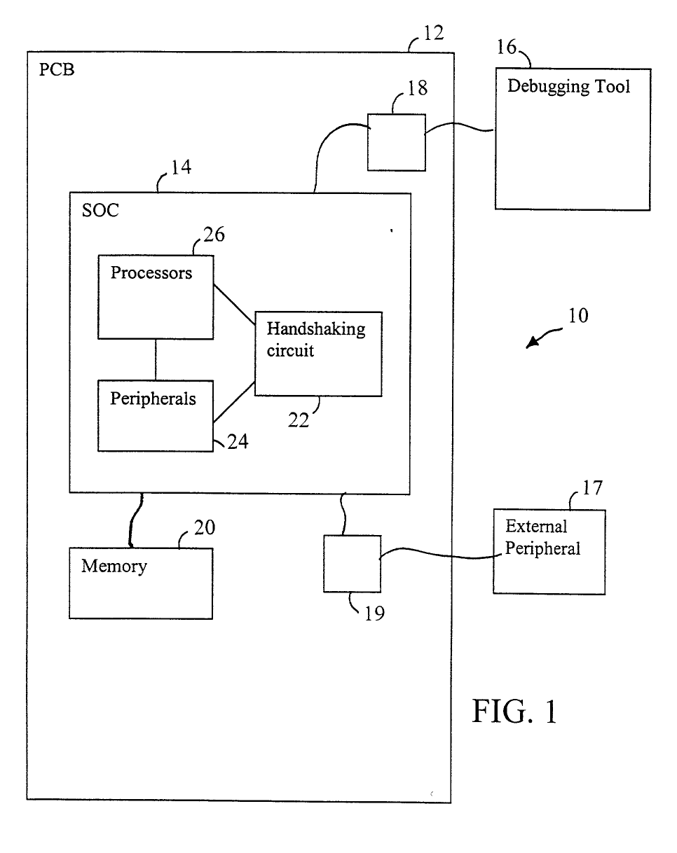

As shown in FIG. 1, a debugging environment 10 includes a debugging tool 16 coupled to a SOC 14 through a debugging interface connector 18. The SOC 14 can contain electronic components such as multiple independent processors 26, peripherals 24, and a digital logic circuit (handshaking circuit) 22 for handling breakpoints when connected to the debugging tool 16. The SOC 14 can reside on a printed circuit board (PCB) 12 which can be part of an electronic device such as a handheld device, computer, cell-phone, or other electronic device. The SOC 14 can be coupled to external memory 20 to store data and/or programs for use by the electronic components inside the SOC. A connector 19 can provide an external peripheral 17 access to electronic signals from components within the SOC 14.

The debugging tool 16 can include hardware and software elements and a user interface that allows a user to test the SOC 14. The debugging tool 16 has the capability to download programs from the tool to the memory 20, which can be loaded into a cache memory inside a processor. The programs may include instructions that can be executed by the processors to allow the processors to interact with the peripherals. The debugging tool 16 has the capability of stepping through a program as it is executed one instruction at a time by the processors. The debugging tool 16 can set an instruction or data breakpoint condition and monitor the execution of the breakpoint condition by using the handshaking circuit to select one or more processors or peripherals in the SOC 14. Once the breakpoint is encountered, the tool in conjunction with the handshaking circuit, can halt execution of the selected processors and peripherals and preserve the state of the processors and the peripherals. The user can then step through the program one instruction at a time to isolate a bug in the SOC 14; or the application software developers can use it to debug their code, to isolate the bugs in the software.

The debugging tool 16 reads registers and data in the processors and the peripherals while the SOC 14 is in a halted state. Once the bug is isolated, the handshaking logic can facilitate resuming operation of the processors and the peripherals and maintain synchronization between the processors and the peripherals. The operation of the handshaking circuit in the SOC 14 is discussed below in detail.

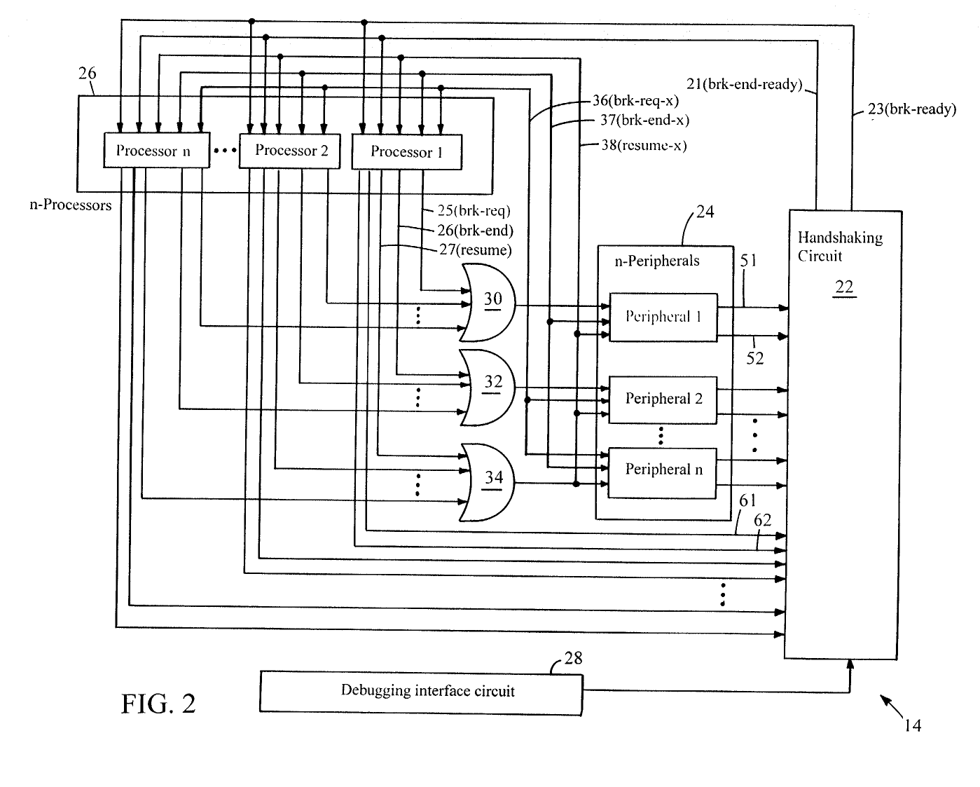

As shown in FIG. 2, the SOC 14 includes processors 26, peripherals 24, and the handshaking circuit 22 that can communicate with one another and with other electronic components in the SOC. A debugging interface circuit 28 may be coupled to each of the components in the SOC 14 allowing the external debugging tool 16 to access the internal components in the SOC. The debugging interface circuit can be configured to operate as a joint text action group (JTAG) or other interface.

The processors 26 can be configured to operate independently and to run at clock rates different from one another. Such processors 26 can include a core processor for providing general purpose processing functions and for managing the overall operation of the SOC 14, a digital signal processor (DSP) for handling specific signal processing tasks, or other processors. Each of the processors 26 may execute programs from memory 20 and store and retrieve data from memory. Each of the processors 26 also can include conventional digital logic circuits such as an arithmetic logic unit (ALU) and registers containing data reflecting the status of the processors.

Each of the processors 26 can generate and process signals such as a first signal through a fifth signal discussed below. For example, a processor such as processor 1, can generate the first signal (“brk-req signal”) on line 25 indicating that the processor has encountered a breakpoint condition previously set by the debugging tool 16. As a result, the processor 1 can transfer control from normal execution of a program residing in memory 20 to a breakpoint handler. Normal execution of a program is defined as the interruption of the routine(s) that would occur in the absence of the breakpoint. A breakpoint handler can be an interrupt handler program that executes when a breakpoint condition is satisfied. The third signal (“brk-end signal”) is generated by the processor 1 on line 26 to indicate that the processor has completed execution of the breakpoint handler. The processor 1 generates the fifth signal (“resume signal”) on line 27 to indicate that the processor has completed the execution of the breakpoint handler and has resumed the normal execution of the program that it is was previously executing.

The processor 1 is configured to receive the second signal (“brk-ready signal”) over line 23 from the handshaking circuit 22 indicating that selected processors and peripherals have been halted and that their respective states have been saved. As will be discussed below in further detail, the handshaking circuit 22 can allow the user to select one or more processors 26 and/or one or more peripherals 24 to participate in a debugging session. In addition, processor 1 can receive the fourth signal (“brk-end-ready signal”) over line 21 from the handshaking circuit 22 indicating that the respective states of the selected processors and peripherals have been restored and that they are ready to resume normal operation. The restoration process can include restoring the saved state that had been previously saved. Each of the processors 26 can generate and process the signals discussed above.

An OR gate 30 receives the brk-req signal from each of the processors 26 and performs a Boolean OR operation. As a result, a brk-req-x signal is generated over line 36 and is fed to each of the peripherals 24 and the processors 26. In a similar fashion, an OR gate 32 receives each brk-end signal from the processors 26, performs a Boolean OR operation, and generates a brk-end-x over line 37 signal which is fed to each of the peripherals 24 and the processors 26. Likewise, an OR gate 34 receives each resume signal from each of the processors 26, performs a Boolean OR operation, and generates a resume-x signal over line 38 which is fed to each of the peripherals 24 and processors 26.

The peripherals 24 can include a universal asynchronous receiver/transmitter (UART) for transmitting and receiving digital signals over a serial port. The peripherals 24 are configured with an input/output (I/O) mechanism such as interrupt structure, direct memory access (DMA), direct access or other I/O mechanism. A peripheral 24, such as peripheral 1, can be configured to receive the brk-req-x signal over line 36 to cause the peripheral to halt operation and to save the state of the peripheral. Once the state of the peripheral 1 is saved, it generates a brk-ready-peripheral signal over line 51 indicating that the state of the peripheral 1 has been saved. Furthermore, the brk-ready-peripheral signal is provided to the handshaking circuit 22 where it is processed with other signals to cause a brk-ready signal to be generated over line 23.

The peripheral 1 is configured to receive the brk-end-x signal over line 37 to cause the peripheral to restore the saved state of the peripheral. Once the state of the peripheral has been restored, it generates a brk-end-ready-peripheral signal over line 52 indicating that the state of the peripheral has been restored. In addition, the brk-end-ready-peripheral signal is provided to the handshaking circuit 22 where it processed with other signals to cause the brk-end-ready signal to be generated over line 21. The peripheral 1 resumes its normal operation when it receives the resume-x signal over line 38.

In a similar fashion, each of the processors 26, such as processor 2, is configured to receive the brk-req-x signal over line 36 to cause the processor to halt normal operation and to save the state of the processor. Once the state of the processor 2 is saved, it generates a brk-ready-processor signal on line 61 indicating that the state of the processor has been saved. The brk-ready-processor signal is provided to the handshaking circuit 22 where it is processed to cause the brk-ready signal to be generated over line 23.

Processor 2 also is configured to receive the brk-end-x signal over line 37 to cause the processor to restore the saved state of the processor. Once the state of the processor has been restored, it generates a brk-end-ready-processor signal on line 62 indicating that the state of the processor has been restored. The brk-end-ready-processor signal is provided to the handshaking circuit 22 where it is processed to cause the brk-end-ready signal over line 21 to be generated. The processor 2 resumes its normal operation when it receives the resume-x signal over line 38.

Each of the peripherals and each of the processors can be configured to generate and process the signals discussed above.

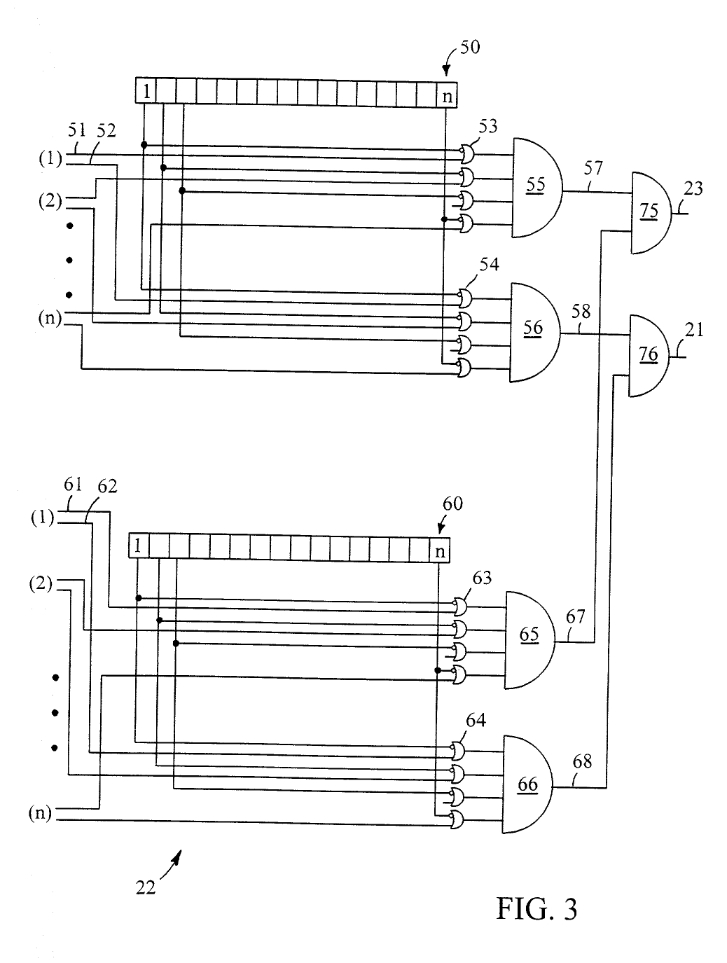

As shown in FIG. 3, the handshaking circuit 22 includes a first register (“peripheral register”) 50 having 1 to n bits. Each bit is associated with a peripheral and allows the user to select one or more peripherals 24 to participate in a debugging session. Each one of the bits is coupled to a first input of a respective OR gate 53. In addition, each one of the bits is coupled to a first input of a respective OR gate 54 associated with an peripheral 24. A second input of the OR gate 53 is coupled to the brk-ready-peripheral signal from line 51. By setting a particular n-bit of the peripheral register 50 to a low value (“0”), brk-ready-peripheral signals from the corresponding peripheral are ignored. On the other hand, by setting the n-bit of the peripheral register 50 to a high value (“1”), brk-ready-peripheral signals from the corresponding peripheral are processed.

The handshaking circuit 22 includes a second register 60 (“processor register”) having 1 to n bits. Each bit is associated with a processor 26 and allows the user to select one or more processors to participate in a debugging session. Each one of the 1 to n bits is coupled to a first input of a respective OR gate 63. In addition, each one of the 1 to n bits is coupled to a first input of a respective OR gate 64 associated with a processor 26. A second input of the OR gate 63 is coupled to the brk-ready-processor signal over line 61 from each of the processors 26. By setting the bit associated with the processor register 60 to a low value (“0”), brk-ready-processor signals from the corresponding processors are ignored. On the other hand, by setting the bit associated with the processor register 60 to a high value (“1”), brk-ready-processor signals from the corresponding processors are processed.

An AND gate 55 generates a signal on line 57 representing the selected peripherals 24 that have halted and that have had their processing states saved. Likewise, an AND gate 65 generates a signal on line 67 representing when the selected processors 26 have halted and saved their processing states. The brk-ready signal is generated by AND gate 75 over line 23 and is based on the signals on line 57 and 67. The brk-ready signal represents the condition that both the selected peripherals 24 and processors 26 have halted and saved their processing states. The signal on line 57 is generated by the AND gate 55 to indicate that the selected peripherals have restored their saved state. Likewise, the signal on line 58 is generated by the AND gate 56 to indicate that the selected processors 26 have restored their saved state.

In a similar fashion, the brk-end-ready signal is generated by AND gate 76 over line 21 based on signals on line 58 and 68. The brk-end-ready signal represents the condition that both the selected peripherals 24 and processors 26 have restored the saved state and are prepared to resume normal processing. The signal on line 58 is generated by the AND gate 56 to indicate that the selected peripherals have restored their saved state. Likewise, the signals on line 68 represent a signal from the AND gate 66 and the OR gates 64 indicating that the selected processors 26 have restored their saved state.

The peripheral register 50 and the processor register 60 may be accessible to the debugging tool 16 through a connection to the debugging interface 28. The user can set the individual n-bits of the registers to select which processor 26 and/or peripherals 24 should be involved in the debugging process.

For example, suppose a user is interested in debugging a SOC 14 that includes a peripheral 1 such as a UART configured to transmit and send data to an external serial port of the SOC. In addition, suppose that processor 1 is a core processor and processor 2 is a DSP.

The user would be able to start and stop the operation of processors 1 and 2 and peripheral 1 by setting a breakpoint condition using the debugger tool. Assuming bit 1 of the peripheral register 50 corresponds to the peripheral 1, the user can set the bit to a high value to cause the peripheral to respond to a breakpoint condition. In addition, assuming bit 1 of the processor register 60 corresponds to processor 1 and bit 2 corresponds to processor 2, the user can set both bits to a high value to cause the processors to halt their operation. Once the breakpoint condition has occurred, the user can debug the processors and peripherals to uncover the problem in the SOC 14. After the problem has been resolved, the user can cause the processing in the SOC 14 to resume. The processors 26 and peripherals 24 that have been selected thorough the registers 50, 60 can resume operation without a experiencing a loss of synchronization among the components.

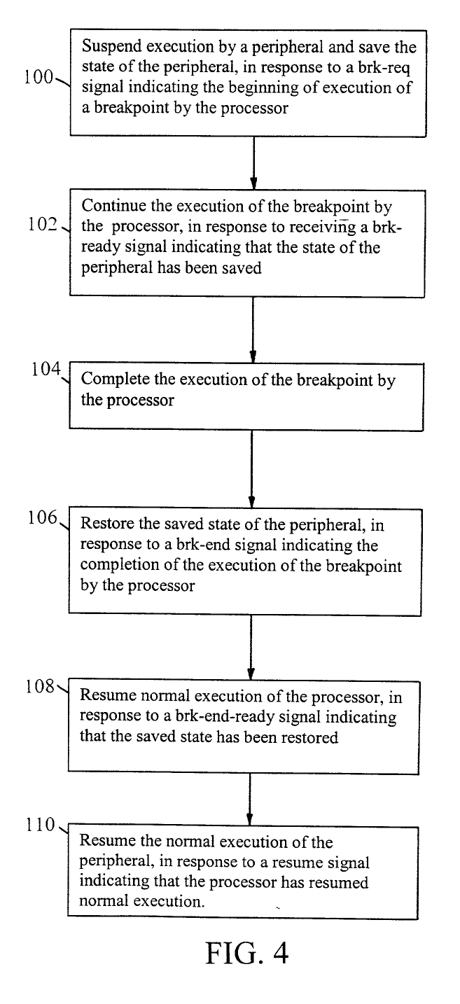

As shown in FIG. 4, normal execution of one or more peripherals 24 is suspended 100 and the state of the suspended peripherals 24 is saved. Normal execution is suspended in response to the generation of a brk-req signal over line 25. The signal indicates the beginning of execution of a breakpoint by one of the processors 26 associated with the breakpoint. As discussed above, one or more peripherals 24 can be selected to participate in the debugging session by setting the corresponding n-bit in the peripheral register 50. In addition, the processor register 60 can be used to select one or more processors 26 to participate in the debugging session and have their respective execution suspension and execution states saved.

Once normal execution of the selected peripherals 24 and/or processors 26 has been suspended (block 100), the selected processors 26 continues 102 execution of the breakpoint. Continuation of the breakpoint is in response to a brk-ready signal generated by the handshaking circuit 22 over line 23 indicating that the state of the peripherals 24 has been saved. During execution of the breakpoint, the user is able step through instructions in memory and to examine various status registers in the peripherals 24, the processors 26, and the SOC 14.

The selected processor 26 completes 104 execution of the breakpoint. As a result, the processor 26 associated with the breakpoint generates a brk-end signal over line 26 indicating that the processor has completed the execution of the breakpoint.

The states of the peripherals 24 that have been selected using the peripheral register 50 and the states of the processors 26 that have been selected using the processor register 60 are restored 106. The states are restored in response to the brk-end signal generated over 26 line from the processor 26 associated with the breakpoint.

The processor 26 associated with the breakpoint resumes 108 it normal operation, in response to the brk-end-ready signal over line 21 generated by the handshaking circuit 22. As discussed above, the brk-end-ready signal indicates that the saved state of the selected processors 26 and peripherals 24 has been restored.

Once the selected processor 26 resumes its normal execution (block 108), the selected peripherals 24 resume normal operation 110. Resumption of normal operation is in response to the resume signal over line 27 indicating that the processors 26 have resumed normal execution. A signal based on the resume signal is received by the selected processors 26 to cause the selected peripherals 24 to resume normal operation.

Use of the handshaking circuit 22 allows the execution of processors 26 and peripherals 24 to operate at different clock rates and to be halted and resumed without a loss of synchronization between the processors and the peripherals. Existing processor and peripheral architectures can be modified to incorporate the handshaking circuit. In addition, processors and peripherals in a SOC can be debugged without the need for additional access pins on the SOC. As a result, the cost of manufacturing the SOC to include the above techniques is minimized.

Various features of the invention can be implemented in hardware, software, or a combination of hardware and software. For example, some aspects of the system can be implemented in hardware such as a application-specific integrated circuit (ASIC), field-programmable gate array (FPGA), or other hardware. In another example, some aspects of the system can be implemented in computer programs executing on programmable computers. Each program can be implemented in a high level procedural or object-oriented programming language to communicate with a computer system. Furthermore, each such computer program can be stored on a storage medium, such as read-only-memory (ROM) readable by a general or special purpose programmable computer or processor, for configuring and operating the computer when the storage medium is read by the computer to perform the functions described above.

Other implementations are within the scope of the following claims.

What is claimed is:

1. A method comprising:
in response to a first signal indicating the execution of a breakpoint by a processor, suspending execution of a peripheral and saving the state of the peripheral;
continuing execution of the breakpoint by the processor in response to receiving a second signal indicating that the state of the peripheral has been saved; and
restoring the saved state of the peripheral in response to a third signal indicating that execution of the breakpoint by the processor has been completed.

2. The method of claim 1 comprising resuming normal execution of the processor in response to a signal indicating that the saved state has been restored.

3. The method of claim 1 comprising resuming normal execution of the peripheral in response to a signal indicating that the processor has resumed normal execution.

4. The method of claim 1 comprising setting a register to control whether generation of the second signal is to be based on the state of the peripheral.

5. The method of claim 1 comprising setting a register to control whether generation of a signal indicating that the saved state has been restored is to be based on the state of the peripheral.

6. The method of claim 1 comprising triggering the breakpoint in response to a condition associated with occurrence of an instruction being executed by the processor.

7. A system comprising:
a processor;
a first computer-readable medium storing instructions that, when applied to the processor, cause the processor to:
generate a first signal indicating execution of a breakpoint,
continue execution of the breakpoint in response to receiving a second signal, and
generate a third signal indicating that execution of the breakpoint has been completed;
a peripheral coupled to the processor;
a second computer-readable medium storing instructions that, when applied to the peripheral, cause the peripheral to:
suspend execution and save a state of the peripheral, in response to receiving the first signal,
restore the state of the peripheral, in response to receiving the third signal; and
a digital logic circuit to generate the second signal indicating that the state of the peripheral has been saved, the digital logic circuit coupled to the processor and the peripheral.

8. The system of claim 7 wherein the first computer-readable medium includes instructions that cause the processor to:
resume normal execution in response to receiving a fourth signal, and
generate a fifth signal indicating that the processor has resumed normal execution; and
wherein the second computer-readable medium includes instructions that cause the peripheral to resume normal execution, in response to receiving the fifth signal; and
wherein the digital logic circuit is configured to generate the fourth signal indicating that the saved state of the peripheral has been restored.

9. The system of claim 8, further comprising:
a second processor;
a third computer-readable medium storing instructions that, when applied to the second processor, cause the second processor to:
suspend execution and save a state of the second processor, in response to receiving the first signal,
restore the state of the second processor, in response to receiving the third signal, and
resume normal execution, in response to receiving the fifth signal; and
the digital logic circuit configured to:
generate the second signal indicating that the state of the second processor has been saved, and
generate the fourth signal indicating that the saved state of the second processor has been restored.

10. The system of claim 7 including a system on a chip (SOC).

11. The system of claim 7 including a debugging tool coupled to the system to debug the system.

12. The system of claim 7 wherein the digital logic circuit comprises a register to control whether generation of the second signal is to be based on the state of the peripheral.

13. The system of claim 7 wherein the state identifies a state of internal registers associated with the peripheral.

14. The system of claim 7 wherein the processor operates at a clock rate different than the peripheral.

15. An apparatus comprising:
a processor having a computer-readable medium storing instructions that, when applied to the processor, cause the processor to:
generate a signal indicating execution of a breakpoint,
continue execution of the breakpoint in response to receiving a signal indicating that the state of a peripheral has been saved, and
generate a signal indicating that execution of the breakpoint has been completed.

16. The apparatus of claim 15 wherein the computer-readable medium includes instructions that cause the processor to resume normal execution in response to a signal indicating that the saved state has been restored.

17. An article comprising a computer-readable medium that stores computer-executable instructions for causing a computer system to:
generate a signal indicating execution of a breakpoint;
continue execution of the breakpoint in response to receiving a signal indicating that the state of a peripheral has been saved; and
generate a signal indicating that execution of the breakpoint has been completed.

18. The article of claim 17 wherein the computer-readable medium stores computer-executable instructions for causing a computer system to resume normal execution of the processor in response to a signal indicating that the saved state has been restored.

19. An apparatus comprising:
a peripheral having a computer-readable medium storing instructions that, when applied to the peripheral, cause the peripheral to:
suspend execution and save a state of the peripheral, in response to receiving a signal indicating execution of a breakpoint, and
restore the state of the peripheral, in response to receiving a signal indicating that execution of the breakpoint has been completed.

20. The apparatus of claim 19 wherein the computer-readable medium includes instructions that cause the peripheral to resume normal execution of the peripheral in response to a signal indicating that a processor has resumed normal execution.

21. An article comprising a computer-readable medium that stores computer-executable instructions for causing a computer system to:
suspend execution and save a state of the peripheral, in response to receiving a signal indicating execution of a breakpoint, and
restore the state of the peripheral, in response to receiving a signal indicating that execution of the breakpoint has been completed.

22. The article of claim 21 wherein the computer-readable medium stores computer-executable instructions for causing a computer system to resume normal execution of the peripheral in response to a signal indicating that a processor has resumed normal execution.

23. An apparatus comprising:
one or more signal lines used to receive signals and to send signals; and
a processor configured to:
generate a signal indicating execution of a breakpoint,
continue execution of the breakpoint in response to receiving a signal on a signal line indicating that the state of a peripheral has been saved, and
generate a signal on a signal line indicating that execution of the breakpoint has been completed.

24. The apparatus of claim 23 wherein the processor is configured to resume normal execution in response to a signal indicating that the saved state has been restored.

25. An apparatus comprising:
one or more signal lines used to receive signals and to send signals; and
a peripheral configured to:
suspend execution and save a state of the peripheral, in response to receiving a signal indicating execution of a breakpoint, and
restore the state of the peripheral, in response to receiving a signal indicating that execution of the breakpoint has been completed.

26. The apparatus of claim 25 wherein the peripheral is configured to resume normal execution in response to a signal indicating that a processor has resumed normal execution.
